(19) United States
(12) Patent Application Publication
(10) Pub. No.: US 2021/0249454 A1
(43) Pub. Date: Aug. 12, 2021

(54) SOLID-STATE IMAGING ELEMENT, METHOD OF MANUFACTURING SOLID-STATE IMAGING ELEMENT, AND ELECTRONIC APPARATUS

(71) Applicant: SONY SEMICONDUCTOR SOLUTIONS CORPORATION, KANAGAWA (JP)

(72) Inventors: RYOJI SUZUKI, TOKYO (US); SHINICHI YOSHIDA, (US); TETSUYA UCHIDA, KANAGAWA (US)

(21) Appl. No.: 17/250,164

(22) PCT Filed: May 10, 2019
(86) PCT No.: PCT/JP2019/018667

§ 371 Date: Dec. 7, 2020

(30) Foreign Application Priority Data
Jun. 15, 2018 (JP) 2018-114546

(51) Int. Cl. H01L 27/146

(52) U.S. Cl. CPC H01L 27/1463; H01L 27/14645; H01L 27/14621; H01L 27/14683; H01L 27/14627; H01L 27/14636; H01L 27/1464; H01L 27/14623

(57) ABSTRACT

A solid-state imaging element according to an embodiment of the present disclosure includes: a semiconductor substrate having a photoelectric converter for each of pixels; a pixel separation groove provided between the pixels, the pixel separation groove extending from one surface of the semiconductor substrate toward another surface of the semiconductor substrate that opposes the one surface; and a pixel coupling section provided between the pixels on the other surface of the semiconductor substrate.

### TECHNICAL FIELD

The present disclosure relates to a solid-state imaging element having a pixel separation groove between pixels, a method of manufacturing the solid-state imaging element, and an electronic apparatus including the solid-state imaging element.

### BACKGROUND ART

In a solid-state imaging device such as a CCD (Charge Coupled Device) image sensor or a CMOS (Complementary Metal Oxide Semiconductor) image sensor, a solid-state imaging element having a photoelectric converter is disposed for each pixel. The photoelectric converter of the solid-state imaging element includes a semiconductor material such as silicon (Si).

For example, PTL 1 discloses a solid-state imaging device in which a photodiode (PD) provided in a semiconductor substrate is completely separated for each pixel by a pixel separation groove is disclosed. In this solid-state imaging device, the semiconductor substrate is completely separated by a pixel separation section, thereby preventing an increase in mixing of colors and occurrence of blooming between adjacent pixels.

### CITATION LIST

### Patent Literature

PTL 1: U.S. Unexamined Patent Application Publication No. 2010/0193845

### SUMMARY OF THE INVENTION

Incidentally, in the solid-state imaging element, flexibility of layout is desired as well as reduction in occurrence of mixing of colors and blooming.

It is desirable to provide a solid-state imaging element, a method of manufacturing the solid-state imaging element, and an electronic apparatus that are able to increase a degree of freedom in a layout.

A solid-state imaging element according to one embodiment of the present disclosure includes: a semiconductor substrate having a photoelectric converter for each of pixels; a pixel separation groove provided between the pixels, the pixel separation groove extending from one surface of the semiconductor substrate toward another surface of the semiconductor substrate that opposes the one surface; and a pixel coupling section provided between the pixels on the other surface of the semiconductor substrate.

A method of manufacturing a solid-state imaging element according to one embodiment of the present disclosure includes: forming a pixel separation groove between pixels of a semiconductor substrate, the pixel separation groove extending from one surface of the semiconductor substrate toward another surface of the semiconductor substrate that opposes the one surface; providing a pixel coupling section between the pixels on the other surface of the semiconductor substrate; and forming a photoelectric converter for each of the pixels.

An electronic apparatus according to one embodiment of the present disclosure includes the solid-state imaging element according to an embodiment of the present disclosure.

In the solid-state imaging element according to one embodiment of the present disclosure, the method of manufacturing the solid-state imaging element according to one embodiment of the present disclosure, and the electronic apparatus according to one embodiment of the present disclosure, provided between adjacent ones of the pixels of the semiconductor substrate having the photoelectric converter for each pixel are the pixel separation groove extending from the one surface of the semiconductor substrate toward the other surface of the semiconductor substrate that opposes the one surface and the pixel coupling section between the pixels of the other surface. This makes it possible to separate adjacent photoelectric converters from each other by the pixel separation groove, and to electrically couple the adjacent pixels to each other by the pixel coupling section.

According to the solid-state imaging element of one embodiment of the present disclosure, and the method of manufacturing the solid-state imaging element of one embodiment of the present disclosure, and the electronic apparatus of one embodiment of the present disclosure, the pixel separation groove extending from the one surface of the semiconductor substrate to the other surface of the semiconductor substrate that opposes the one surface is provided between the adjacent pixels and the pixel coupling section is provided on the other surface; therefore, it is possible to separate the adjacent photoelectric converters and to electrically couple the adjacent pixels to each other. Therefore, it becomes possible to increase the degree of freedom of the layout.

It is to be noted that effects described here are not necessarily limited and any of effects described in the present disclosure may be included.

### BRIEF DESCRIPTION OF DRAWINGS

FIG. 1 is a schematic cross-sectional view of a solid-state imaging element according to a first embodiment of the present disclosure.

FIG. 2 is another schematic cross-sectional view of the solid-state imaging element illustrated in FIG. 1.

FIG. 3 is a schematic plan view of the solid-state imaging element illustrated in FIG. 1.

FIG. 4 is a schematic plan view of a semiconductor substrate of the solid-state imaging element illustrated in FIG. 1.

FIG. 5A is a schematic cross-sectional view for describing a process of manufacturing the solid-state imaging element illustrated in FIG. 1.

FIG. 5B is a schematic cross-sectional view of a process following FIG. 5A.

FIG. 5C is a schematic cross-sectional view of a process following FIG. 5B.

FIG. 5D is a schematic cross-sectional view of a process following FIG. 5C.

FIG. 5E is a schematic cross-sectional view of a process following FIG. 5D.

FIG. 5F is a schematic cross-sectional view of a process following FIG. 5E.

FIG. 6 is a schematic plan view for describing a shape of the pixel separation groove according to a modification example 1 of the present disclosure.

FIG. 7 is a schematic plan view for describing a shape of the pixel separation groove according to a modification example 2 of the present disclosure.

FIG. 8 is a schematic plan view of a solid-state imaging element having a pixel separation groove pattern illustrated in FIG. 7.

FIG. 9 is a schematic plan view of a solid-state imaging element according to a modification example 3 of the present disclosure.

FIG. 10 is a schematic cross-sectional view of the solid-state imaging element illustrated in FIG. 9.

FIG. 11 is a schematic cross-sectional view of a main part illustrating an example of a solid-state imaging element according to a modification example 4 of the present disclosure.

FIG. 12 is a schematic cross-sectional view of a main part illustrating an example of a body of the solid-state imaging element according to the modification example 4 of the present disclosure.

FIG. 13 is a schematic cross-sectional view of a main part illustrating an example of a body of the solid-state imaging element according to the modification example 4 of the present disclosure.

FIG. 14 is a schematic plan view of an example of a pattern of the pixel separation groove of a solid-state imaging element according to a modification example 5 of the present disclosure.

FIG. 15 is a schematic plan view of another example of a pattern of the pixel separation groove of a solid-state imaging element according to the modification example 5 of the present disclosure.

FIG. 16 is a schematic cross-sectional view for describing an example of a method of manufacturing the solid-state imaging element according to the modification example 5.

FIG. 17, part (a) is a schematic plan view of a surface S1 of a semiconductor substrate of a solid-state imaging element according to a second embodiment of the present disclosure, and part (b) is a schematic plan view of a surface S2 thereof.

FIG. 18A is a schematic cross-sectional view for describing a process of manufacturing the solid-state imaging element according to the second embodiment of the present disclosure.

FIG. 18B is a schematic cross-sectional view of a process following FIG. 18A.

FIG. 18C is a schematic cross-sectional view of a process following FIG. 18B.

FIG. 18D is a schematic cross-sectional view of a process following FIG. 18C.

FIG. 18E is a schematic cross-sectional view of a process following FIG. 18D.

FIG. 18F is a schematic cross-sectional view of a process following FIG. 18E.

FIG. 18G is a schematic cross-sectional view of a process following FIG. 18F.

FIG. 18H is a schematic cross-sectional view of a process following FIG. 18G.

FIG. 18I is a schematic cross-sectional view of a process following FIG. 18H.

FIG. 18J is a schematic cross-sectional view of a process following FIG. 18I.

FIG. 19 is a schematic cross-sectional view of a solid-state imaging element manufactured using a method according to the present disclosure.

FIG. 20 is a schematic plan view of the solid-state imaging element illustrated in FIG. 19.

FIG. 21, part (a) is a schematic plan view of a pixel separation groove pattern of STI of a solid-state imaging element according to a third embodiment of the present disclosure, part (b) is a schematic plan view of a pixel separation groove pattern of a surface S1 thereof, and part (c) is a schematic plan view of a pixel separation groove pattern of a surface S2 thereof.

FIG. 22A is a schematic cross-sectional view for describing a process of manufacturing the solid-state imaging element according to the third embodiment of the present disclosure.

FIG. 22B is a schematic cross-sectional view of a process following FIG. 22A.

FIG. 22C is a schematic cross-sectional view of a process following FIG. 22B.

FIG. 22D is a schematic cross-sectional view of a process following FIG. 22C.

FIG. 22E is a schematic cross-sectional view of a process following FIG. 22D.

FIG. 22F is a schematic cross-sectional view of a process following FIG. 22E.

FIG. 22G is a schematic cross-sectional view of a process following FIG. 22F.

FIG. 22H is a schematic cross-sectional view of a process following FIG. 22G.

FIG. 22I is a schematic cross-sectional view of a process following FIG. 22H.

FIG. 23 is a schematic cross-sectional view of a solid-state imaging element manufactured using a method according to the present disclosure.

FIG. 24 is a schematic plan view of the solid-state imaging element illustrated in FIG. 23.

FIG. 25 is a block diagram illustrating an overall configuration of an imaging device including the photoelectric conversion element illustrated in FIG. 1.

FIG. 26 is a functional block diagram illustrating an example of an imaging apparatus (camera) including the imaging device illustrated in FIG. 25.

FIG. 27 is a block diagram depicting an example of a schematic configuration of an in-vivo information acquisition system.

FIG. 28 is a view depicting an example of a schematic configuration of an endoscopic surgery system.

FIG. 29 is a block diagram depicting an example of a functional configuration of a camera head and a camera control unit (CCU).

FIG. 30 is a block diagram depicting an example of schematic configuration of a vehicle control system.

FIG. 31 is a diagram of assistance in explaining an example of installation positions of an outside-vehicle information detecting section and an imaging section.

### MODES FOR CARRYING OUT THE INVENTION

In the following, some embodiments of the present disclosure are described in detail with reference to the drawings. The following description is given of specific examples of the present disclosure, and the present disclosure is not limited to the following embodiments. Moreover, the present disclosure is not limited to positions, dimensions, dimension ratios, and the like of respective components illustrated in the respective drawings. It is to be noted that description is given in the following order.

1. First Embodiment (An example of a solid-state imaging element provided with a pixel coupling section at a bottom of a pixel separation groove)

1-1. Configuration of Solid-State Imaging Element

1-2. Method of Manufacturing Solid-State Imaging Element

1-3. Workings and Effects

2. Modification Examples

2-1. Modification Example 1

2-2. Modification Example 2

2-3. Modification Example 3

2-4. Modification Example 4

2-5. Modification Example 5

3. Second Embodiment (An example of another method of manufacturing a solid-state imaging element having a pixel coupling section)

4. Third Embodiment (An example of another method of manufacturing a solid-state imaging element having a pixel coupling section)

5. Application Examples (Examples of application to electronic apparatuses)

### 1. FIRST EMBODIMENT

### [1-1. Configuration of Solid-State Imaging Element]

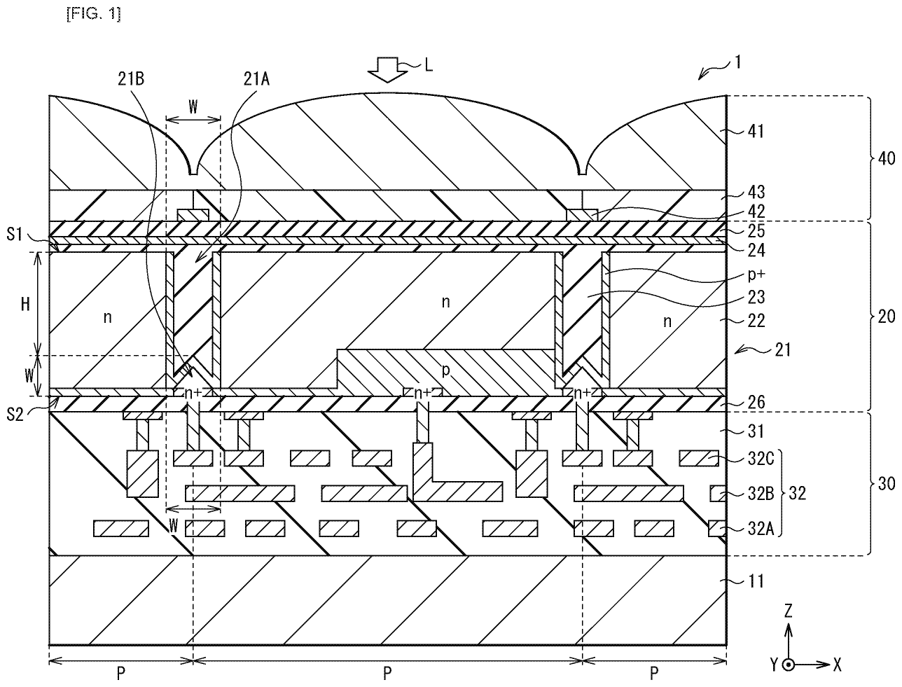

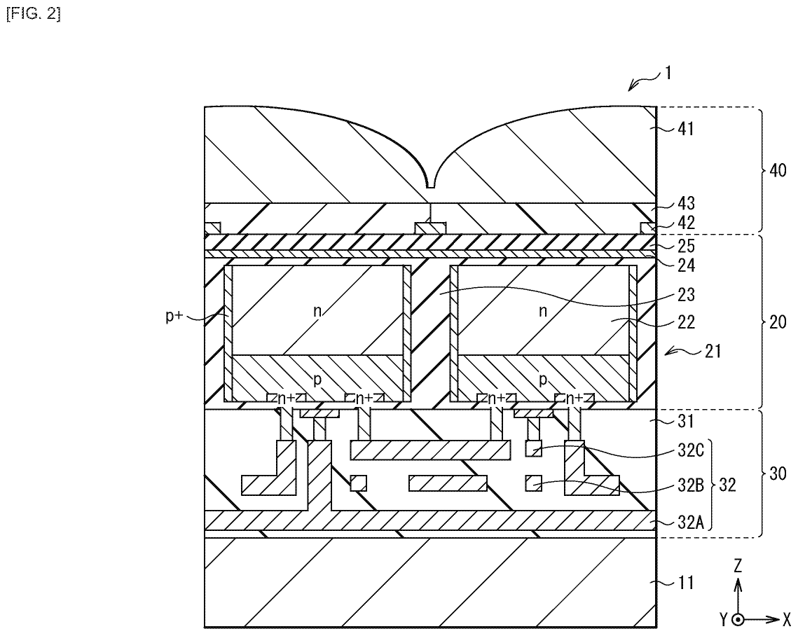

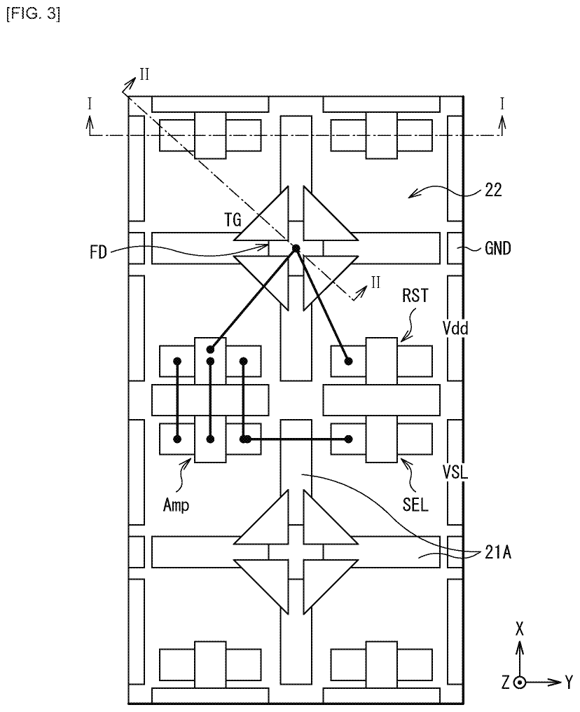

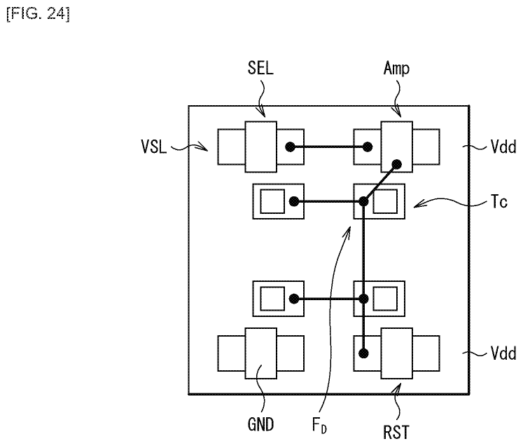

FIG. 1 illustrates a cross-sectional configuration of a solid-state imaging element (solid-state imaging element 1) according to a first embodiment of the present disclosure taken along a line II-II illustrated in FIG. 3. FIG. 2 illustrates a cross-sectional configuration of the solid-state imaging element 1 taken along a line I-I illustrated in FIG. 3. FIG. 3 schematically illustrates a planar configuration of the solid-state imaging element 1 according to the present disclosure. In a solid-state imaging device (solid-state imaging device 100) such as a CMOS image sensor (see FIG. 24), the solid-state imaging element 1 includes one pixel (for example, a pixel P). The solid-state imaging element 1 is a back-side illumination type, and has a configuration in which a light condensing section 40 is provided on light incident surface side of a light reception section 20 having a photoelectric converter 22, and a wiring layer 30 is provided on a surface opposite to the light incident surface side. The light reception section 20 includes: a semiconductor substrate 21; the photoelectric converter 22 provided for each pixel P; an insulating film 23 provided on the light incident surface (light reception surface, back surface: surface S1) side of the semiconductor substrate 21; a low-reflective film 24; a protective film 25; and an insulating film 26 provided on front surface (surface S2) side of the semiconductor substrate 21. The present embodiment has a configuration in which a pixel separation groove 21A extending from the surface S1 toward the surface S2 and a pixel coupling section 21B provided on the surface S2 of the semiconductor substrate 21 are provided between pixels.

Hereinafter, the configuration of the solid-state imaging element 1 will be described in the order of the light reception section 20, the wiring layer 30, and the light condensing section 40. It is to be noted that in the present embodiment, a case is described where electrons are read out as signal charges (a case where an n-type semiconductor region serves as the photoelectric conversion layer), out of pairs of electrons and holes generated by photoelectric conversion. In addition, in the drawings, “+(plus)” attached to “p” or “n” indicates that a p-type or n-type impurity concentration is high compared to an ambient p-type semiconductor region or n-type semiconductor region.

### [Light Reception Section]

The light reception section 20 includes, for example: the semiconductor substrate 21 into which a photodiode (PD) including the photoelectric converter 22 is fitted; the pixel separation groove 21A extending from the back surface (surface S1) of the semiconductor substrate 21 toward the front surface (surface S2), the insulating film 23 with which the pixel separation groove 21A is filled and which is provided on an entirety of the surface S1 of the semiconductor substrate 21; the low-reflective film 24 and the protective film 25 which are sequentially stacked on the insulating film 23; and the insulating film 26 provided on an entirety of the surface S2 of the semiconductor substrate 21. Further, the pixel coupling section 21B that electrically couples the pixels to each other is provided on the surface S2 of the semiconductor substrate 21.

The semiconductor substrate 21 includes, for example, silicon (Si), and as described above, is provided with the pixel separation groove 21A extending in a thickness direction (Z direction) of the semiconductor substrate 21 between pixels on the light reception surface S1 side. A depth (height (H)) of the pixel separation groove 21A may be any height at which wavelengths of interest are sufficiently absorbed, and for example, in a case where the wavelengths of interest are symmetrically visible-light, it is preferable that the depth be 2 μm or more and 15 μm or less. A width (W) may be any width at which it is possible to perform optical separation and impurity diffusion, and at which a photoelectric conversion region is not widely scraped, and it is preferable that the width be, for example, 20 nm or more and 30% or less of a pixel size.

The semiconductor substrate 21 remains at a bottom of the pixel separation groove 21A (the surface S2 of the semiconductor substrate 21) to form the pixel coupling section 21B. The pixel coupling section 21B electrically couples adjacent pixels to each other, and includes, for example, a p-type semiconductor region. As will be described in detail later, the pixel coupling section 21B has a convex shape having a slope on a side surface, a height (thickness (h)) of 1 μm or less, for example, and a width (w) of 1 μm or less, for example. A tilt angle (θ) of the pixel coupling section 21B is preferably, for example, 20° or more with respect to a normal direction (Z-axis direction) of a plane of the semiconductor substrate 21. A p+ region having a thickness of, for example, approximately 50 nm is formed on the side surface of the pixel separation groove 21A. This increases a capacity of the photoelectric converter 22 including an n-type semiconductor region, which will be described later. Further, the p+ region is also formed on a front surface of the pixel coupling section 21B.

Near the front surface (surface S2) of the semiconductor substrate 21, a transfer transistor (TG) that transfers signal charges generated in the photoelectric converter 22 to, for example, an FD (see FIG. 3) is disposed. A gate electrode TG of the transfer transistor is provided in the wiring layer 30, for example. The signal charges may be either electrons or holes generated by the photoelectric conversion, and will be described here with reference to a case of reading electrons as the signal charges as an example.

Near the surface S2 of the semiconductor substrate 21, for example, a reset transistor (RST), an amplifier transistor (Amp), a selection transistor (SEL) and the like are provided together with the transfer transistor (TG). Such transistors are, for example, each a MOSEFT (Metal Oxide Semiconductor Field Effect Transistor), and form a circuit for each pixel P. Each circuit may have a three-transistor configuration including, for example, the transfer transistor (TG), the reset transistor (RST), and the amplifier transistor (Amp), or may have a four-transistor configuration in which the selection transistor (SEL) is added to the three-transistor configuration. It is also possible to share between pixels the transistors other than the transfer transistor (TG).

The photoelectric converter 22 is, for example, the n-type semiconductor region formed in the thickness direction (Z direction) of the semiconductor substrate 21 (here, a Si substrate) for each pixel P, and is a photodiode of a p-n junction type with the p-type semiconductor region provided on the front surface (surface S2) of the semiconductor substrate 21.

Each of the insulating films 23 and 26 is formed using, for example, silicon oxide (SiO₂). It is to be noted that the pixel separation groove 21A provided on the back surface (surface S1) of the semiconductor substrate 21 is filled with the insulating film 23.

The low-reflective film 24 is provided on the insulating film 23 on the back surface (surface S1) side of the semiconductor substrate 21. Examples of a material of the low-reflective film 24 include hafnium oxide (HfO₂), zirconium oxide (ZrO₂), aluminum oxide (Al₂O₃), titanium oxide (TiO₂), tantalum oxide (Ta₂O₅), and the like.

The protective film 25 is provided on the low-reflective film 24 to planarize the back surface of the semiconductor substrate 21. The protective film 25 includes, for example, a single layer film such as silicon nitride (Si₂N₃), silicon oxide (SiO₂), and silicon oxynitride (SiON), or a stacked film thereof.

### [Wiring Layer]

The wiring layer 30 is provided in contact with the front surface (surface S2) of the semiconductor substrate 21. The wiring layer 30 includes a plurality of wiring lines 32 (e.g., wiring lines 32A, 32B, and 32C) via an interlayer insulating film 31. The wiring layer 30 is bonded to a support substrate 11 including, for example, Si, and is disposed between the support substrate 11 and the semiconductor substrate 21.

### [Light Condensing Section]

The light condensing section 40 is provided on the light reception surface S1 side of the light reception section 20, and includes an on-chip lens 41 which are oppositely disposed on the photoelectric converter 22 of each of the pixels P as an optical functional layer on the light incident side. A color filter 43 is stacked between the light reception section 20 (specifically, the protective film 25) and the on-chip lens 41. Further, a light-shielding film 42 is provided on the protective film 25 between the pixels.

The on-chip lens 41 has a function of condensing light toward the light reception section 20 (specifically, the photoelectric converter 22 of the light reception section 20).

The light-shielding film 42 is provided between the pixels of the protective film 25, for example, on the pixel separation groove 21A. The light-shielding film 42 suppresses mixing of colors due to crosstalk of obliquely incident light between adjacent pixels. Examples of a material of the light-shielding film 42 include tungsten (W), aluminum (Al), an alloy of aluminum (Al) and copper (Cu), and the like.

The color filter 43 is, for example, a red (R) filter, a green (G) filter, or a blue (B) filter, and is provided for each pixel P, for example. The color filters 43 are arranged in regular colored arrangement (e.g., Bayer arrangement). Provision of such color filters 43 enables the solid-state imaging element 1 to obtain light-receiving data of a color corresponding to the color arrangement.

### [1-2. Method of Manufacturing Solid-State Imaging Element]

The solid-state imaging element 1 according to the present embodiment may be manufactured, for example, as follows.

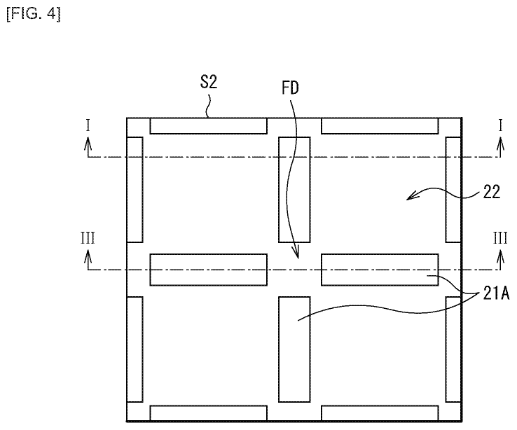

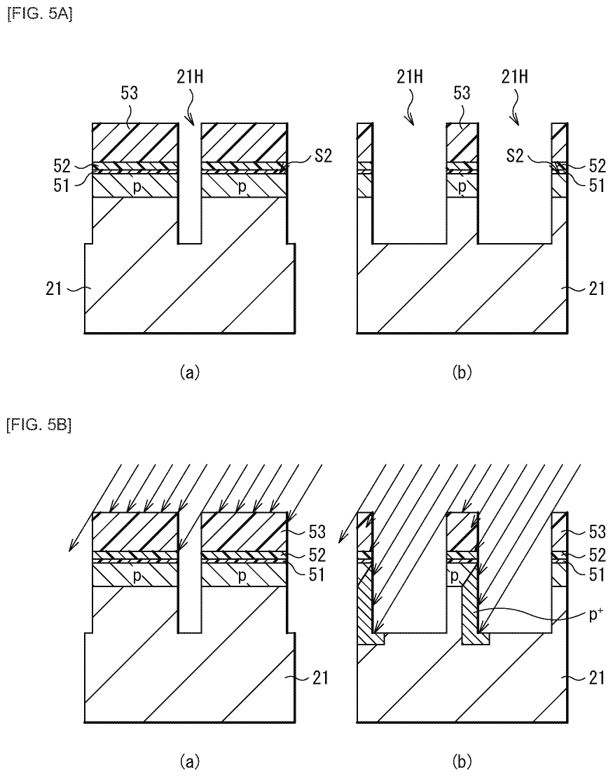

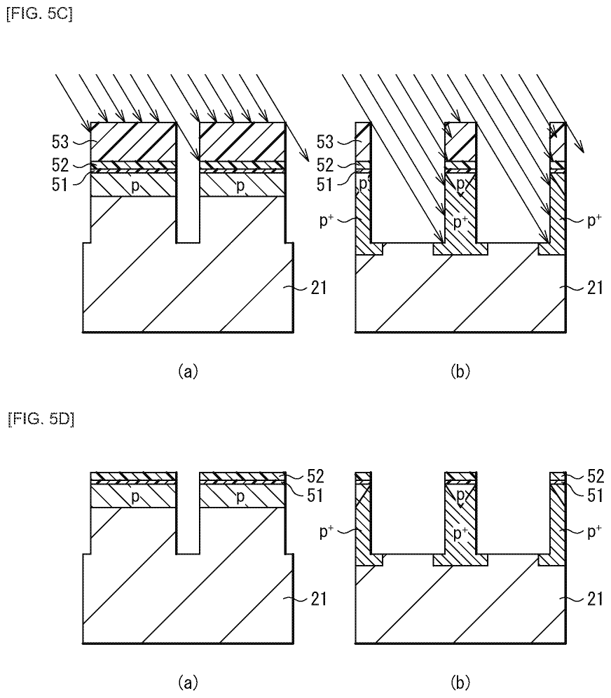

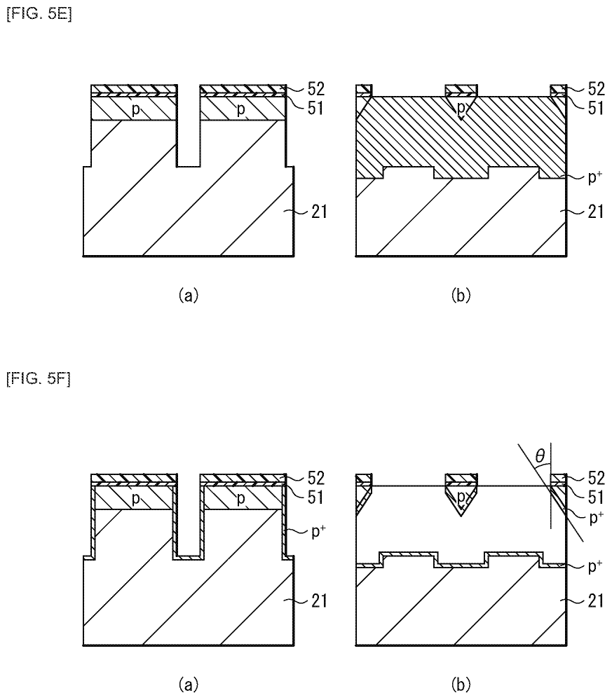

FIG. 4 schematically illustrates a planar configuration of the pixel separation groove 21A on the front surface (surface S2) side of the semiconductor substrate 21 of the solid-state imaging element 1. FIGS. 5A to 5F illustrate a method of manufacturing the solid-state imaging element 1 in order of processes. Parts (a) of FIGS. 5A to 5F each represent a cross-sectional configuration taken along a line I-I illustrated in FIG. 4, and parts (b) thereof each represent a cross-sectional configuration taken along a line III-III illustrated in FIG. 4.

First, as illustrated in FIG. 5A, a SiO₂ film 51 and a Si₃N₄ film 52 are provided over the front surface (surface S2) of the semiconductor substrate 21 having a p-well on the front surface (surface S2). Next, after patterning a resist film 53 on the Si₃N₄ film 52, a trench 21H to be the pixel separation groove 21A is formed from the surface S2 side by etching. Subsequently, as illustrated in FIG. 5B, boron (B) is ion-implanted into the semiconductor substrate 21 with a tilt angle so as to have a density of, for example, about 1e18 cm⁻³ or more to form a p+ region. At this time, in the I-I cross section, boron (B) is not implanted into the semiconductor substrate 21 because the trench 21H is narrow and shadows the resist film 53. Subsequently, as illustrated in FIG. 5C, boron (B) is ion-implanted into the semiconductor substrate 21 again with a changed tilt angle so as to have a density of, for example, about 1e18 cm⁻³ or more to form the p+ region. It is to be noted that the tilt angle be, for example, 20° or more with respect to the normal direction (Z-axis direction) of the plane of the semiconductor substrate 21.

Next, as illustrated in FIG. 5D, the resist film 53 is peeled off. Subsequently, as illustrated in FIG. 5E, the p+ region is selectively etched by using a chemical having a high etching rate in the p-type region, such as fluoro-nitric acid and acetic acid, for example. As a result, under the SiO₂ film 51 and the Si₃N₄ film 52, the p-type semiconductor region which is not ion-implanted by the shielding of the resist film 53 and the Si₃N₄ film 52 remains, and the pixel coupling section 21B is formed. Next, as illustrated in FIG. 5F, the p+ region is formed by plasma doping using B₂H₆, for example, on the front surface of the semiconductor substrate 21 exposed by etching. It is to be noted that the p+ region may be formed by solid phase diffusion or vapor phase diffusion besides the plasma doping.

Thereafter, the trench 21H is filled with a SiO₂ film and the SiO₂ film is formed on the semiconductor substrate 21 using, for example, an ALD method. After that, the front surface (surface S1) of the semiconductor substrate 21 is planarized using a CMP method, for example. Next, using a method similar to a CIS of a normal back-side illumination type, an n-type region of the photoelectric converter 22, the transistors, the wiring lines, etc., are formed from the front surface (surface S2) side, and thereafter, the surface S2 of the semiconductor substrate 21 is bonded to a wafer in which the support substrate and a circuitry are formed. Subsequently, the back surface (surface S1) of the semiconductor substrate 21 is thinned until the trench 21H is exposed. Next, on the back surface (surface S1) side of the semiconductor substrate 21, for example, a HfO₂ film is formed as the low-reflective film 24 using the ALD method or a CVD method, for example, and, for example, a SiO₂ film is formed as the protective film 25 using the ALD method or a MOCVD method, for example.

Subsequently, after forming, for example, a W film on the protective film 25 using a sputtering method or the CVD method, for example, patterning is performed by photolithography or the like, thereby forming the light-shielding film 42. Next, over the protective film 25 and the light-shielding film 42, the color filter 43 and the on-chip lens 41 are formed in this order, for example, and the color filters 43 are in a Bayer arrangement. In this way, the solid-state imaging element 1 may be obtained.

### [Operation of Solid-State Imaging Element]

In such a solid-state imaging element 1, serving as one of the pixels P of the solid-state imaging device 100, for example, signal charges (electrons in this case) are acquired as follows. Upon entering of the light L through the on-chip lens 41 into the solid-state imaging element 1, the light L passes through the color filter 43 or the like and is detected (absorbed) by the photoelectric converter 22 in each pixel P, and red, green, or blue light is photoelectrically converted. Among the electron-hole pairs generated in the photoelectric converter 22, the electrons move to the semiconductor substrate 21 (e.g., the n-type semiconductor region in the Si substrate) and accumulate, and the holes move to the p-type region and are discharged.

### [1-3. Workings and Effects]

For a solid-state imaging element, a structure has been proposed in which pixels of the solid-state imaging element are completely separated from each other by an insulating film, to prevent mixing of colors and blooming from occurring. In this structure, it is necessary to dispose a well contact for each pixel. Thus, there is an issue that a layout efficiency can be lowered.

In addition, in a structure in which a pixel separation section is provided in a back surface (light incident surface) of a semiconductor substrate, there is an issue that blooming can be deteriorated because a portion between photodiodes (PDs) of adjacent pixels is coupled by Si. Further, in this structure, the pixel separation section is formed after forming transistors and wiring lines, thus, there is an issue that it is difficult to sufficiently perform recovery of an etching damage caused by heat treatment.

In contrast, in the present embodiment, the pixel coupling section 21B is provided between adjacent pixels of the semiconductor substrate 21 having the photoelectric converter 22 for each pixel, at the bottom of the pixel separation groove 21A extending from the back surface (surface S1) to the front surface (surface S2) of the semiconductor substrate 21. This makes it possible for the adjacent photoelectric converters 22 to be separated from each other by the pixel separation groove 21A, and the adjacent pixels to be electrically coupled to each other by the pixel coupling section 21B.

As described above, the solid-state imaging element according to the present embodiment is provided with the pixel separation groove 21A between adjacent pixels on the back surface (surface S1) of the semiconductor substrate 21, and the pixel coupling section 21B on the front surface (surface S2) of semiconductor substrate 21, specifically, on the bottom surface of the pixel separation groove 21A. Thus, it is possible to separate the adjacent photoelectric converters 22 and electrically couple the adjacent pixels. Therefore, it is not necessary to dispose a well contact for each pixel P, and hence, it is possible to increase the degree of freedom in the layout.

In addition, in the present embodiment, the pixel separation groove 21A is provided on the back surface (surface S1) of the semiconductor substrate 21 between the adjacent pixels, and the pixel coupling section 21B has a convex shape having a slope on the side surface, thus, a path of charges to the photoelectric converter 22 provided in the adjacent pixels P is reduced. Therefore, overflow components flowing to the photoelectric converter 22 provided in the adjacent pixel P are reduced, and it becomes possible to prevent blooming. In addition, it is possible to prevent mixing of colors between the adjacent pixels.

Further, in the present embodiment, the trench to be the pixel separation groove 21A is formed prior to forming the transistors and the wiring lines; therefore, it is possible to recover the damage caused by the heat treatment performed when forming the trench. Still further, impurities are uniformly introduced into a sidewall of the trench by the plasma doping, the solid phase diffusion, the vapor phase diffusion, or the like after forming the trench to form the p+ region, thereby making it possible to increase a quantity of saturated signals in the photoelectric converter 22.

### 2. MODIFICATION EXAMPLES

### 2-1. Modification Example 1

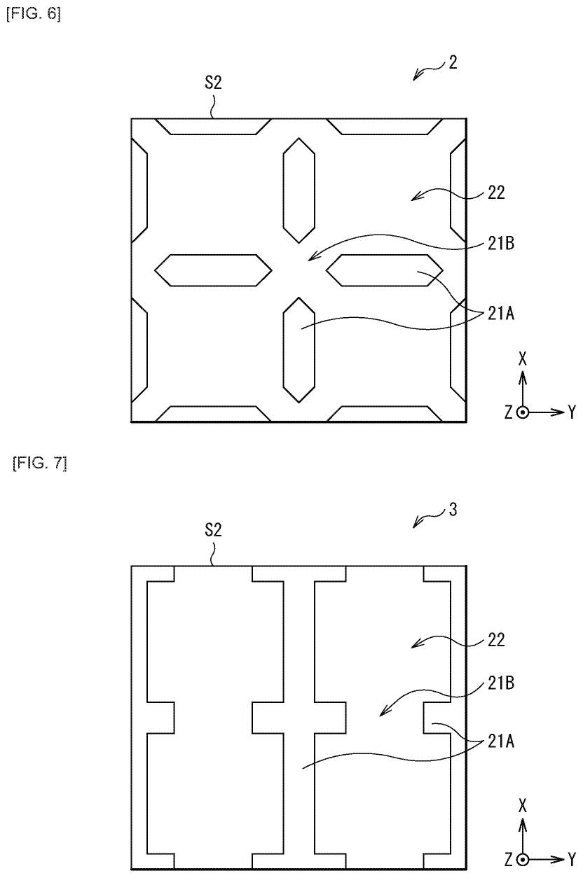

FIG. 6 schematically illustrates a planar configuration of the pixel separation groove 21A on the front surface (surface S2) of the semiconductor substrate 21 of a solid-state imaging element 2 according to a modification example 1 of the present disclosure. An end of the pixel separation groove 21A may have a shape as illustrated in FIG. 6. This makes it possible to shorten a distance between the pixel separation grooves 21A that are directly opposed to each other, and for example, in the processes illustrated in FIG. 5B and FIG. 5C, it becomes possible to join the p+ regions by ion implantation at lower energies or ion implantation at lower angles. Therefore, it becomes possible to reliably join the trenches to be the pixel separation grooves 21A while leaving the pixel coupling section 21B.

### 2-2. Modification Example 2

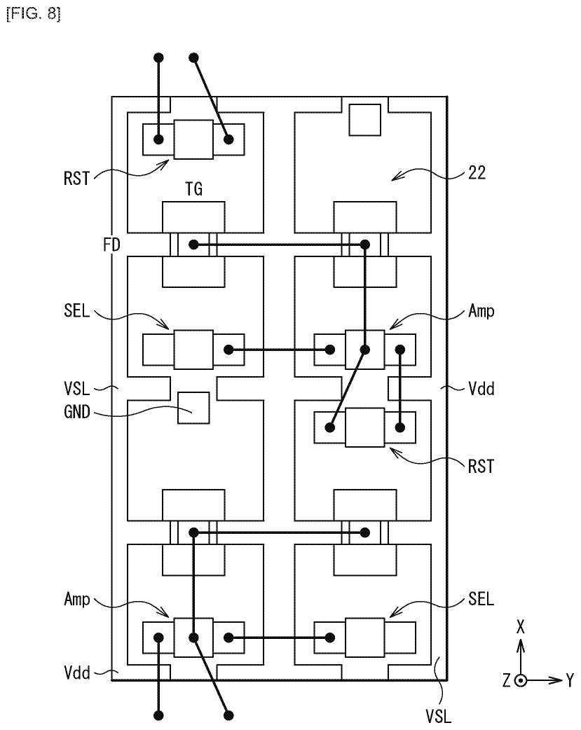

FIG. 7 schematically illustrates a planar configuration of the pixel separation groove 21A on the front surface (surface S2) of the semiconductor substrate 21 of a solid-state imaging element 3 according to a modification example 2 of the present disclosure. FIG. 8 schematically illustrates a planar configuration of the solid-state imaging element 3 according to the present disclosure. Although the above embodiment illustrates an example in which the pixel coupling section 21B is provided at the intersection of pixels P disposed in two rows and two columns, for example, the present disclosure is not limited thereto. For example, as illustrated in FIG. 7, the pixel coupling section 21B may be provided, for example, in the middle between pixels adjoining in the Y-axis direction, for example.

### 2-3. Modification Example 3

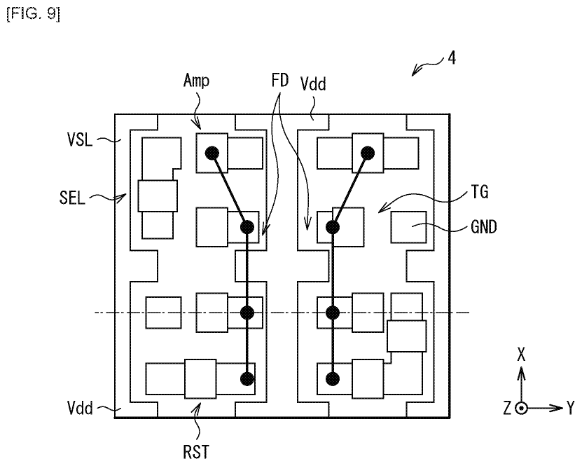

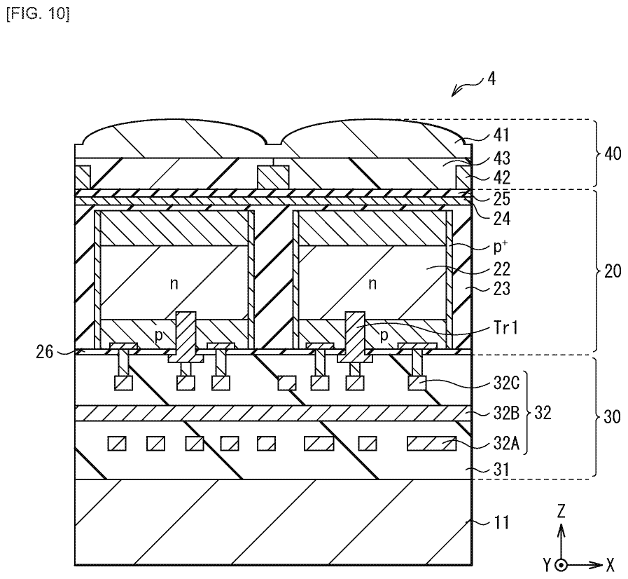

FIG. 9 schematically illustrates a planar configuration of a solid-state imaging element 4 according to a modification example 3 of the present disclosure. FIG. 10 schematically illustrates a cross-sectional configuration of the solid-state imaging element 4 illustrated in FIG. 9. The solid-state imaging element 4 is obtained by stacking the photoelectric converter 22 and various transistors such as the reset transistor (RST), the amplifier transistor (Amp), and the selection transistor (SEL) in the Z-axis direction, and signals may be read using a vertical transistor Tr1 from the photoelectric converter 22.

### 2-4. Modification Example 4

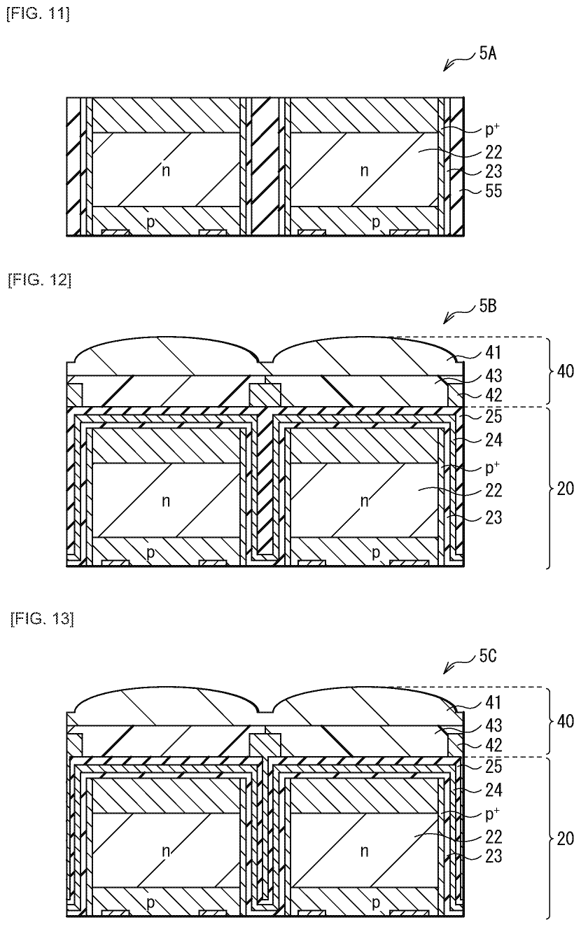

FIGS. 11 to 13 respectively illustrate cross-sectional configurations of main parts of solid-state imaging elements 5A to 5C according to a modification example 4 of the present disclosure. In the above embodiment, an example in which the pixel separation groove 21A is filled with the insulating film 23 such as SiO₂ has been described, but the present disclosure is not limited thereto. For example, as in the solid-state imaging element 5A illustrated in FIG. 11, a polysilicon 55 may be filled after the insulating film 23 film is formed on the side surface and the bottom surface of the pixel separation groove 21A. As illustrated in the solid-state imaging element 5B, after the insulating film 23 with which the trench 21H is filled from the front surface (surface S2) side of the semiconductor substrate 21 is etched from the back surface (surface S1) side of the semiconductor substrate 21, the low-reflective film 24 may be formed as a fixed-charge film on the back surface (surface S1) of the semiconductor substrate 21, on the top surface of the insulating film 23 and the side surface and the bottom surface of the pixel separation groove 21A. Further, as the solid-state imaging element 5C illustrated in FIG. 13, for example, the light-shielding film 42 provided between pixels may extend into the pixel separation groove 21A. This makes it possible to further suppress the mixing of colors between adjacent pixels.

### 2-5. Modification Example 5

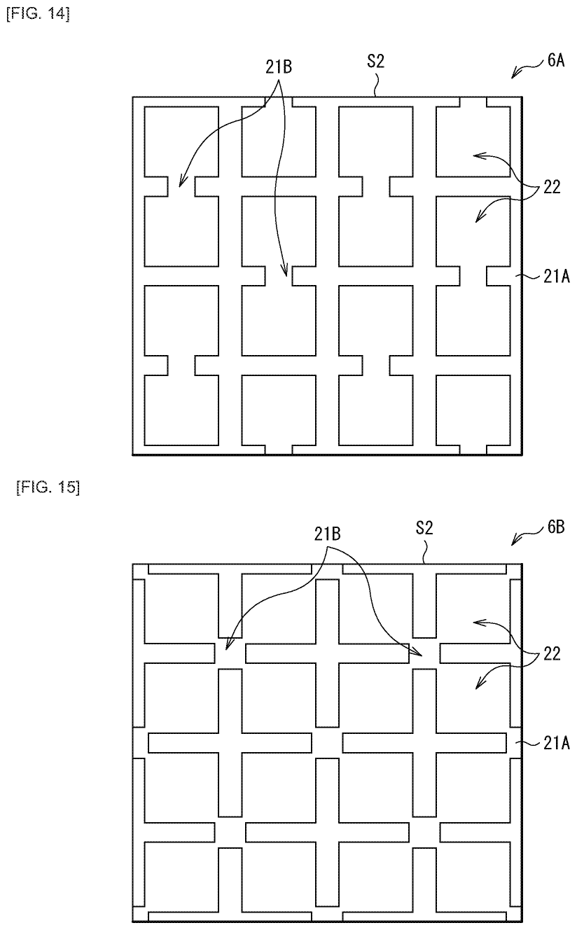

FIG. 14 schematically illustrates an example of a planar pattern of the pixel separation groove 21A on the front surface (surface S2) of the semiconductor substrate 21 of a solid-state imaging element 6A according to a modification example 5 of the present disclosure. FIG. 15 schematically illustrates another example of a planar pattern of the pixel separation groove 21A on the front surface (surface S2) of the semiconductor substrate 21 of a solid-state imaging element 6B according to the modification example 5 of the present disclosure. FIGS. 14 and 15 illustrates pixels P disposed in four rows and four columns.

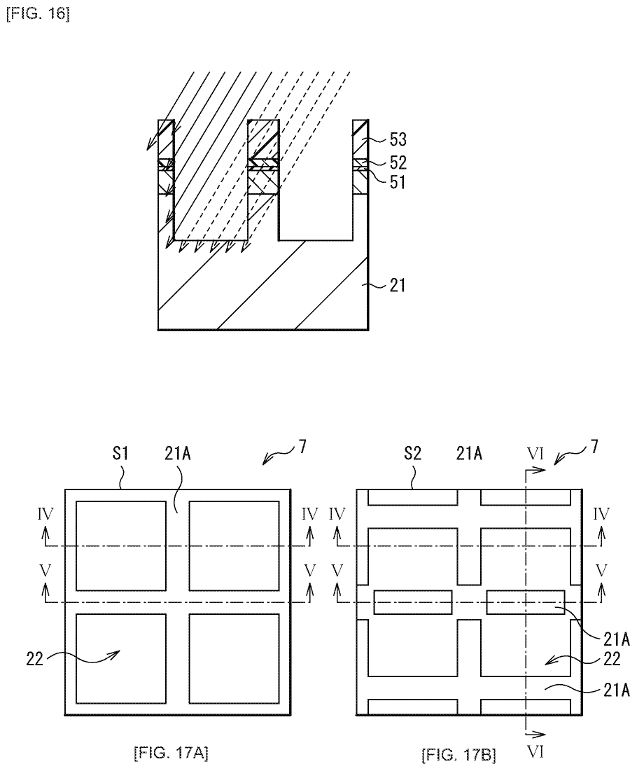

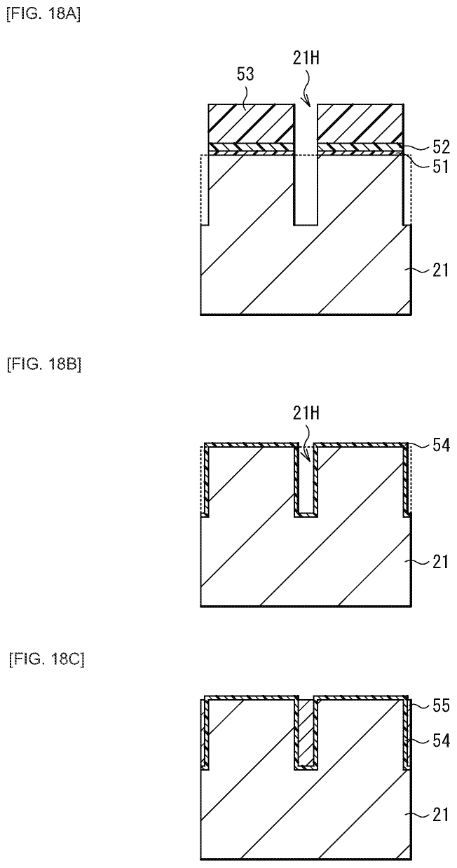

In a solid-state imaging element, in a case where a pixel size is small, there is a possibility that the resist film 53 may become a shadow, which makes it difficult to perform the ion implantation up to the bottom surface, as described in the above embodiment. In such a case, it is not necessary to provide the pixel coupling section 21B between each of all adjacent pixels. As in the solid-state imaging elements 6A and 6B illustrated in FIGS. 14 and 15, one pixel coupling section 21B may be provided to every two adjacent pixels. Further, in a case where the pixel size is small, the ion implantation may be performed across a plurality of pixels P as illustrated in FIG. 16. Alternatively, the ion implantation may be performed by reducing an ion implantation angle with respect to the normal direction (Z-axis direction) of the X-Y plane of the semiconductor substrate 21, for example.

### 3. SECOND EMBODIMENT

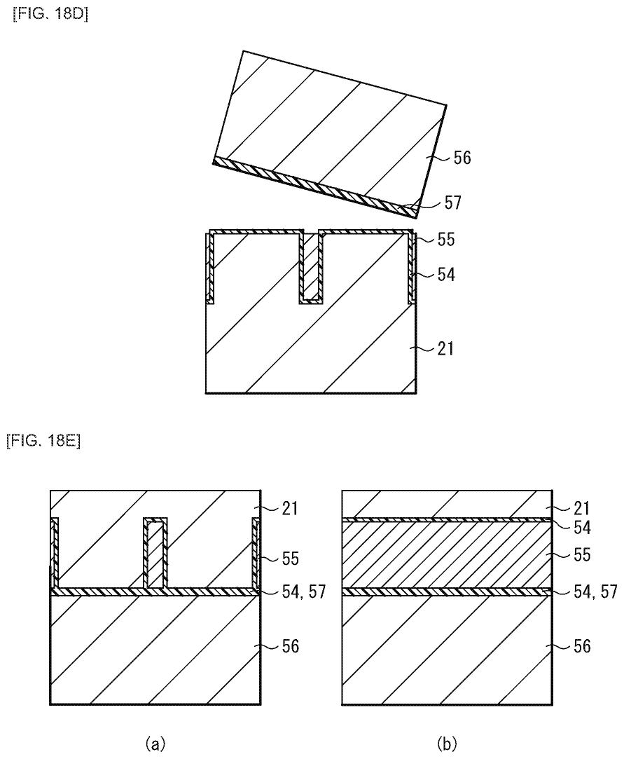

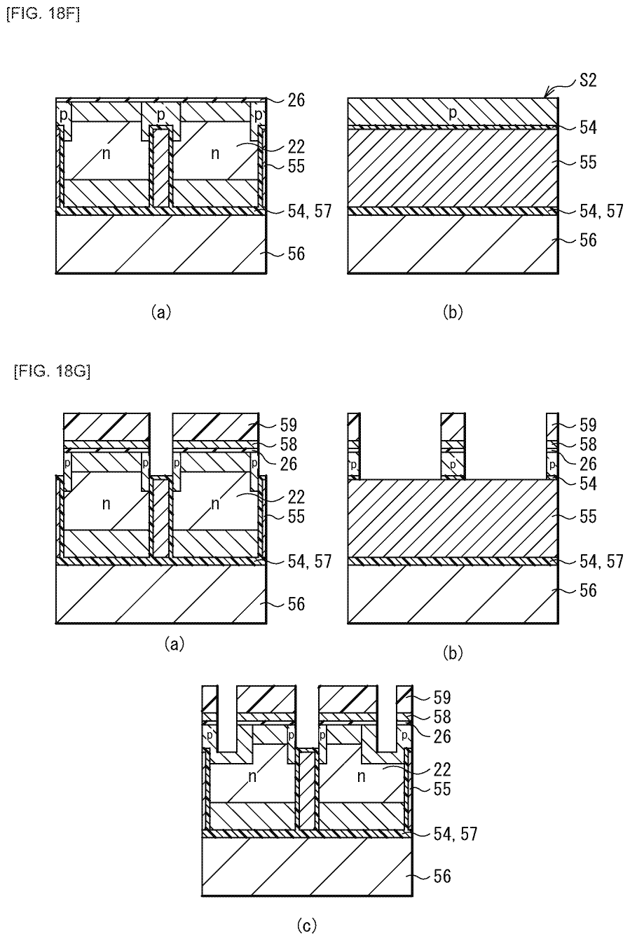

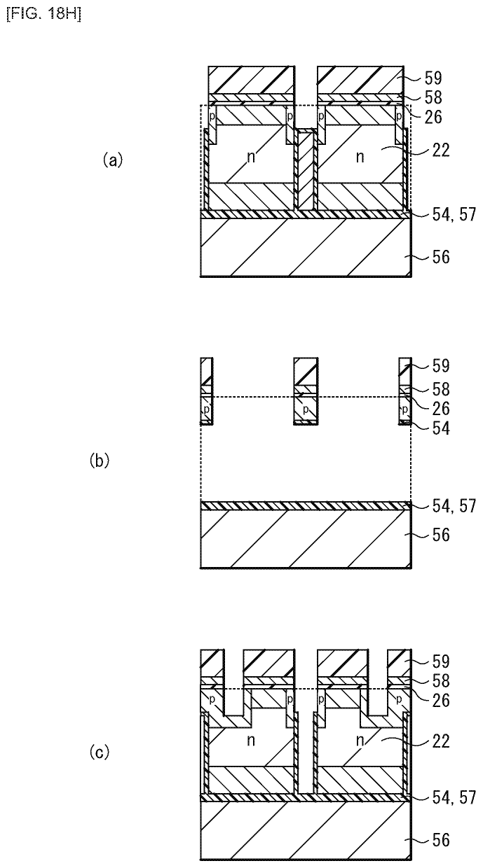

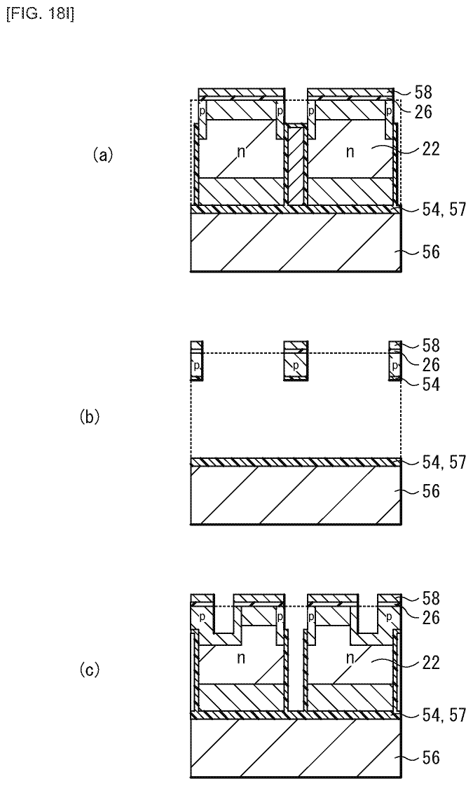

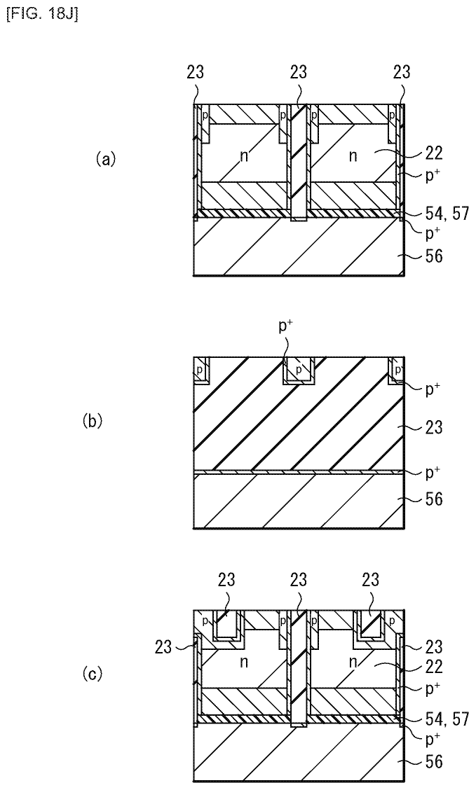

FIG. 17 schematically illustrates a planar configuration of the pixel separation groove 21A on the back surface (surface S1, (a)) and a planar configuration of the pixel separation groove 21A on the front surface (surface S2, (b)), of the semiconductor substrate 21 of a solid-state imaging element (solid-state imaging element 7) according to a second embodiment of the present disclosure. FIGS. 18A to 18J illustrate a method of manufacturing the solid-state imaging element 1 in order of processes. Parts (a) of FIGS. 18E to 18J each represent a cross-sectional configuration taken along a line IV-IV illustrated in FIG. 17, parts (b) thereof each represent a cross-sectional configuration taken along a line V-V illustrated in FIG. 17, and parts (c) thereof each represent a cross-sectional configuration taken along a line VI-VI illustrated in FIG. 17.

First, as illustrated in FIG. 18A, the SiO₂ film 51 and the Si₃N₄ film 52 are provided over the back surface (surface S1) of the semiconductor substrate 21, the resist film 53 is patterned thereon, and thereafter, the trench 21H to be the pixel separation groove 21A is formed by etching. Subsequently, as illustrated in FIG. 18B, the Si₃N₄ film 52 and the SiO₂ film 51 are sequentially etched, and thereafter, a SiO₂ film 54 is formed on the back surface (surface S1) of the semiconductor substrate 21 and the side surface and the bottom surface of the trench 21H using the ALD method.

Next, as illustrated in FIG. 18C, the polysilicon 55 is formed into a film on the back surface (surface S1) of the semiconductor substrate 21 and inside the trench 21H using the CVD method, for example, and then a front surface is polished using the CMP method. Subsequently, as illustrated in FIG. 18D, a support substrate 56 having a SiO₂ film 57 is film-bonded to the back surface (surface S1) of the semiconductor substrate 21 from a surface on which the SiO₂ film 57 is formed. Next, as illustrated in FIG. 18E, the semiconductor substrate 21 is inverted, and the semiconductor substrate 21 is thinned from the front surface (surface S2) side. Subsequently, as illustrated in FIG. 18F, the n-type semiconductor region is formed in the semiconductor substrate 21 thereby forming the photoelectric converter 22, and thereafter, the p-well is formed on the front surface (surface S2) of the semiconductor substrate 21.

Next, as illustrated in FIG. 18G, a SiO₂ film 26 and a Si₃N₄ film 58 are formed over the front surface (surface S2) of the semiconductor substrate 21, and a resist film 59 is patterned thereon, and then a front surface of the trench 21H formed from the back surface (surface S1) side of the semiconductor substrate 21 is exposed by etching. Subsequently, as illustrated in FIG. 18H, polysilicon with which the trench 21H is filled is etched.

Next, as illustrated in FIG. 18I, after etching the SiO₂ film at the bottom of the trench 21H, for example, the p+ region is formed on the sidewall and the bottom surface of the trench 21H by plasma doping using B₂H₆. It is to be noted that the solid phase diffusion or the vapor phase diffusion may be used besides the plasma doping.

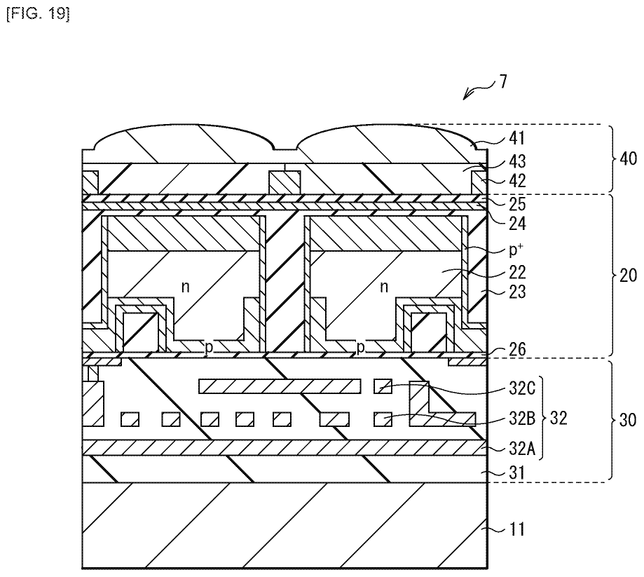

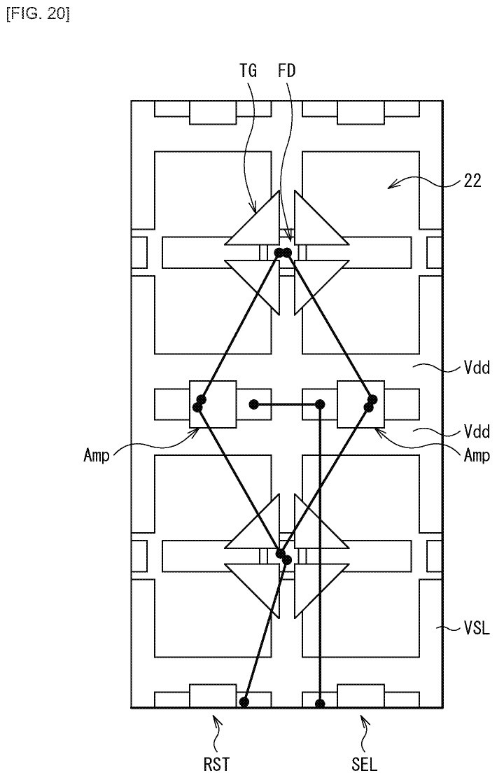

Subsequently, as illustrated in FIG. 18J, after the trench 21H is filled with the SiO₂ film using the ALD method, for example, the front surface of the SiO₂ film is polished with CMP, for example. Thereafter, the solid-state imaging element 7 illustrated in FIG. 19 is completed through processes similar to those of the first embodiment. It is to be noted that a planar configuration of the solid-state imaging element 7 is as illustrated in FIG. 20.

In the manufacturing method according to the present modification example, a portion of the trench 21H on the back surface (surface S1) side may be overlapped with the trench 21H on the front surface (surface S2) side; therefore, the degree of freedom in the layout on transistor surface (front surface (surface S2)) side is further increased.

It is to be noted that, in the present embodiment, an example has been described in which the pixel separation groove 21A is formed from the back surface (surface S1) side of the semiconductor substrate 21, then STI is formed from the front surface (surface S2) side of the semiconductor substrate 21, and the pixel separation groove 21A and the STI are coupled to each other. However, the present disclosure is not limited thereto. For example, the trench and the STI coupled to the pixel separation groove 21A from the front surface (surface S2) side may be formed separately. In this case, p-n junction isolation may be used as in the above-described first embodiment without using the STI.

### 4. THIRD EMBODIMENT

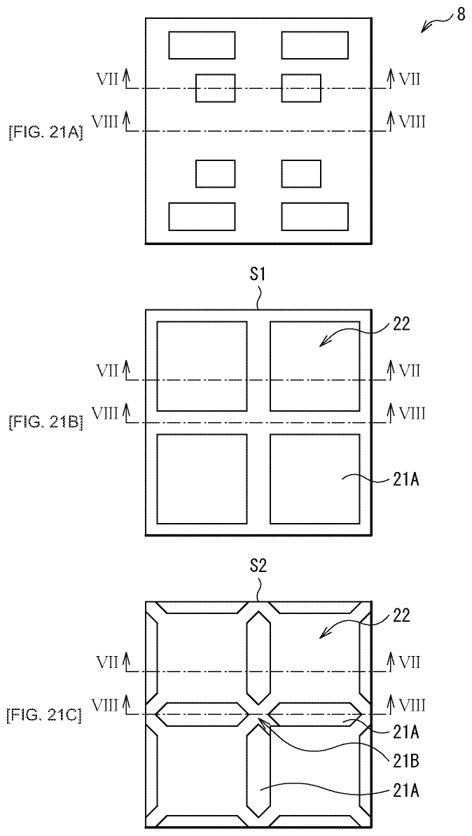

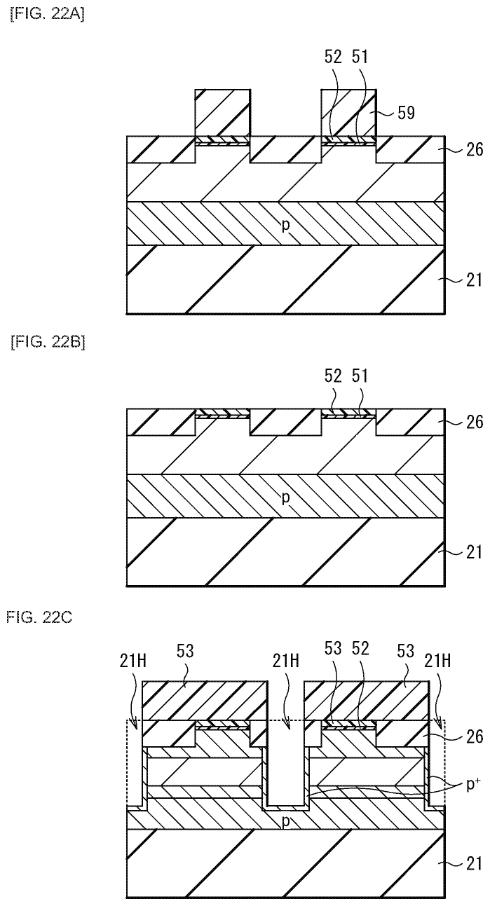

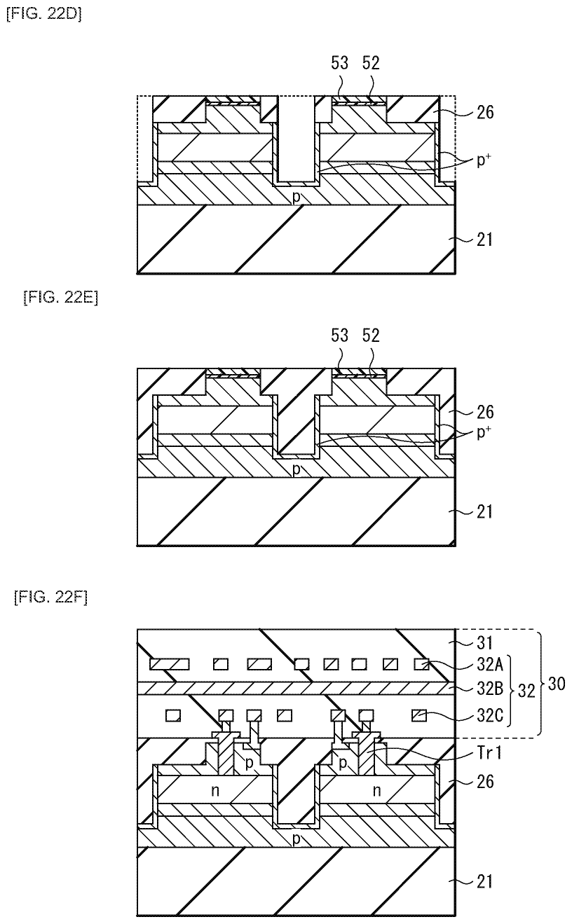

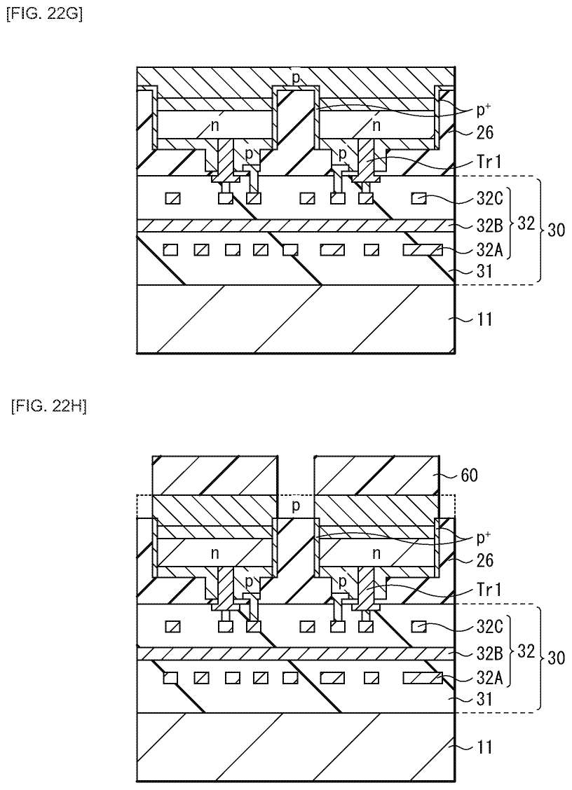

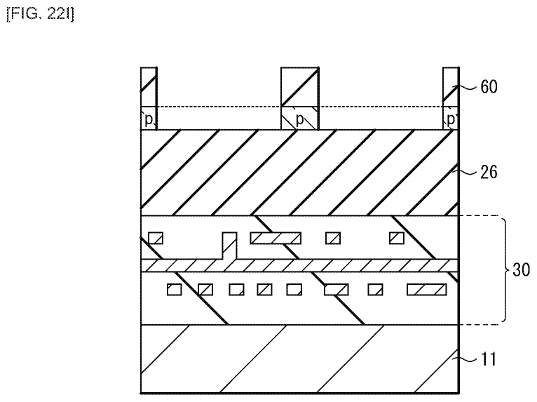

FIG. 21 schematically illustrates a planar configuration of STI (a), a planar configuration of the front surface (surface S2, (b)) of the semiconductor substrate 21, and a planar configuration of the back surface (surface S1, (c)) of the semiconductor substrate 21, of a solid-state imaging element (solid-state imaging element 8) according to a third embodiment of the present disclosure. FIGS. 22A to 22I illustrate a method of manufacturing the solid-state imaging element 1 in order of processes.

First, as illustrated in FIG. 22A, the SiO₂ film 51 and the Si₃N₄ film 52 are provided over the front surface (surface S2) of the semiconductor substrate 21 in which the p-well is formed in the middle, and the resist film 53 is patterned thereon, and then the semiconductor substrate 21 is etched to form the STI. Subsequently, as illustrated in FIG. 22B, after forming the SiO₂ film 26 on the semiconductor substrate 21 using the CVD method, for example, a front surface of the SiO₂ film 26 is polished with CMP, for example. Next, as illustrated in FIG. 22C, after patterning the resist film 53 on the semiconductor substrate 21, the trench 21H to be the pixel separation groove 21A is formed by etching.

Subsequently, as illustrated in FIG. 22D, after peeling off the resist film 53, for example, the p+ region is formed on the sidewall and the bottom surface of the trench 21H by plasma doping using B₂H₆. It is to be noted that solid phase diffusion or vapor phase diffusion may be used besides the plasma doping. Next, as illustrated in FIG. 22E, for example, after forming the SiO₂ film 26 using the CVD method, a front surface is polished using the CMP method.

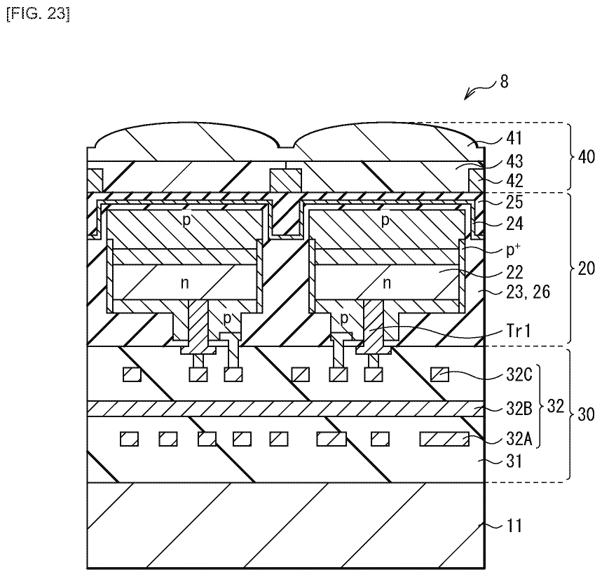

Subsequently, as illustrated in FIG. 22F, after forming the n-type semiconductor region to be the photoelectric converter 22 in the semiconductor substrate 21, various transistors, wiring lines 32, and the like are formed on the front surface (surface S2) side of the semiconductor substrate 21, thereby forming the wiring layer 30. It is to be noted that the n-type semiconductor region (photoelectric converter 22) may be formed prior to the STI process. Thereafter, as illustrated in FIG. 22G, the semiconductor substrate 21 is inverted and the support substrate 11 is bonded to the wiring layer 30. Next, as illustrated in FIG. 22H, after forming a resist film 60 on the back surface (surface S1) side of the semiconductor substrate 21, a position corresponding to FIG. 21 (c) is etched. It is to be noted that FIG. 22I illustrates a cross-sectional configuration taken along a line VIII-VIII line in this process. Thereafter, the solid-state imaging element 7 illustrated in FIG. 23 is completed through processes similar to those of the first embodiment. It is to be noted that a planar configuration of the solid-state imaging element 7 is as illustrated in FIG. 24.

In the manufacturing method according to the present modification example, it is possible to reduce the number of processes as compared with the manufacturing method according to the first embodiment, and to reduce manufacturing costs. Further, compared with the manufacturing method according to the second embodiment, the number of times of bonding is reduced by one, which is advantageous in terms of costs.

### 5. APPLICATION EXAMPLES

### Application Example 1

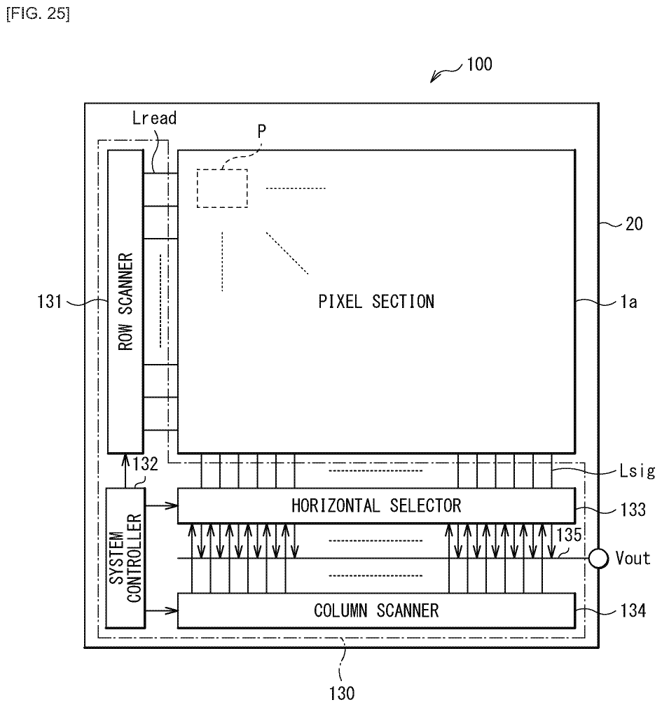

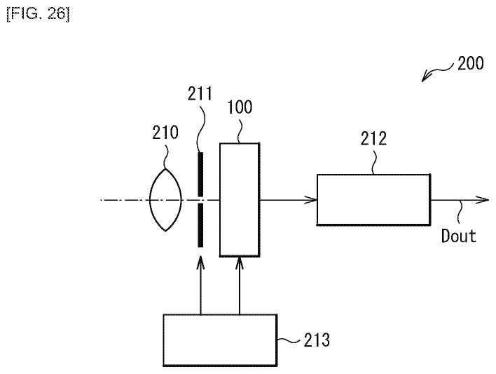

FIG. 25 illustrates an overall configuration of the solid-state imaging device 100 using, for each of the pixels, the solid-state imaging element 1 described in the above-described embodiment. The solid-state imaging device 100 is a CMOS image sensor, and includes, on the semiconductor substrate 21, a pixel section 1a as an imaging region and a peripheral circuit section 130 including, for example, a row scanner 131, a horizontal selector 133, a column scanner 134, and a system controller 132 in a peripheral region of the pixel section 1a.

The pixel section 1a has a plurality of unit pixels P (each corresponding to the solid-state imaging element 1) two-dimensionally arranged in a matrix, for example. The unit pixels P are wired with pixel drive lines Lread (specifically, row selection lines and reset control lines) for respective pixel rows, and vertical signal lines Lsig for respective pixel columns, for example. The pixel drive lines Lread transmit drive signals for signal reading from the pixels. The pixel drive lines Lread each have one end coupled to a corresponding one of output terminals, corresponding to the respective rows, of the row scanner 131.

The row scanner 131 includes a shift register, an address decoder, and the like, and is a pixel driver, for example, that drives the respective unit pixels P in the pixel section 1a on a row-by-row basis. A signal outputted from each of the unit pixels P of a pixel row selectively scanned by the row scanner 131 is supplied to the horizontal selector 133 through each of the vertical signal lines Lsig. The horizontal selector 133 includes an amplifier, a horizontal selection switch, and the like provided for each of the vertical signal lines Lsig.

The column scanner 134 includes a shift register, an address decoder, and the like, and drives respective horizontal selection switches of the horizontal selector 133 in sequence while scanning the horizontal selection switches. Such selective scanning by the column scanner 134 causes the signals of the respective pixels transmitted through the respective vertical signal lines Lsig to be outputted in sequence to a horizontal signal line 135 and thereafter transmitted to outside of the semiconductor substrate 21 through the horizontal signal line 135.

Circuit components including the row scanner 131, the horizontal selector 133, the column scanner 134, and the horizontal signal line 135 may be formed directly on the semiconductor substrate 21 or disposed in an external control IC. Alternatively, these circuit components may be formed in any other substrate coupled by a cable, or the like.

The system controller 132 receives a clock given from the outside of the semiconductor substrate 21, or data or the like on instructions of operation modes, and also outputs data such as internal information of the solid-state imaging device 100. The system controller 132 further has a timing generator that generates various timing signals, and performs drive control of the peripheral circuits such as the row scanner 131, the horizontal selector 133, and the column scanner 134, on the basis of the various timing signals generated by the timing generator.

### Application Example 2

The above-described solid-state imaging device 100 is applicable to, for example, various kinds of electronic apparatuses having imaging functions. Examples of the electronic apparatuses include camera systems such as digital still cameras and video cameras and mobile phones having the imaging functions. FIG. 26 illustrates, for purpose of an example, a schematic configuration of a camera 200. The camera 200 is a video camera that enables shooting of a still image or a moving image, for example, and includes the solid-state imaging device 100, an optical system (optical lens) 310, a shutter device 311, a driver 313 that drives the solid-state imaging device 100 and the shutter device 311, and a signal processor 312.

The optical system 310 guides image light (incident light) from an object to the pixel section 1a of the solid-state imaging device 100. The optical system 310 may include a plurality of optical lenses. The shutter device 311 controls a period in which the solid-state imaging device 100 is irradiated with the light and a period in which the light is blocked. The driver 313 controls a transfer operation of the solid-state imaging device 100 and a shutter operation of the shutter device 311. The signal processor 312 performs various types of signal processing on signals outputted from the solid-state imaging device 100. An image signal Dout having been subjected to the signal processing is stored in a storage medium such as a memory or outputted to a monitor, or the like.

### Application Example 3

### [Example of Practical Application to In-Vivo Information Acquisition System]

Further, the technology (present technology) according to the present disclosure is applicable to various products. For example, the technology according to the present disclosure may be applied to an endoscopic surgery system.

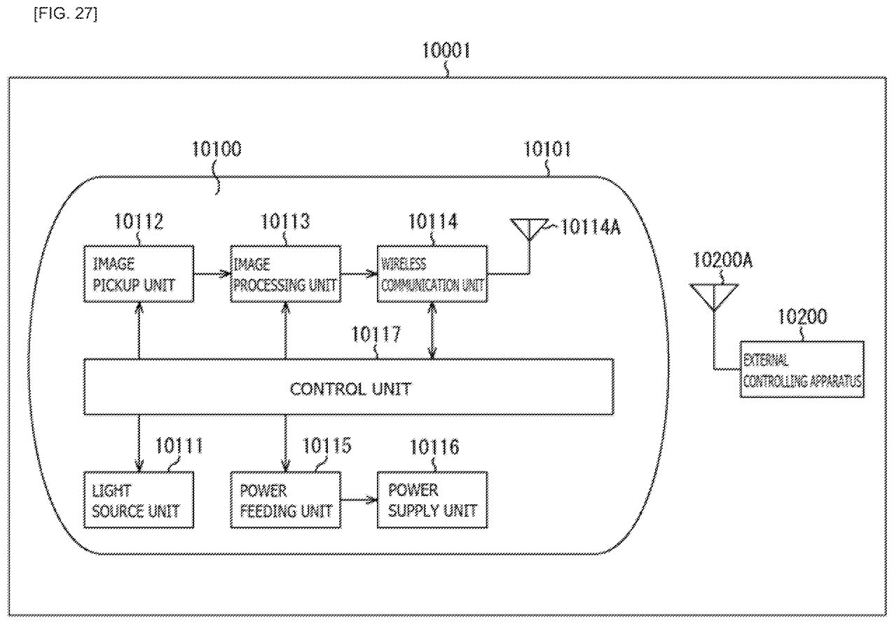

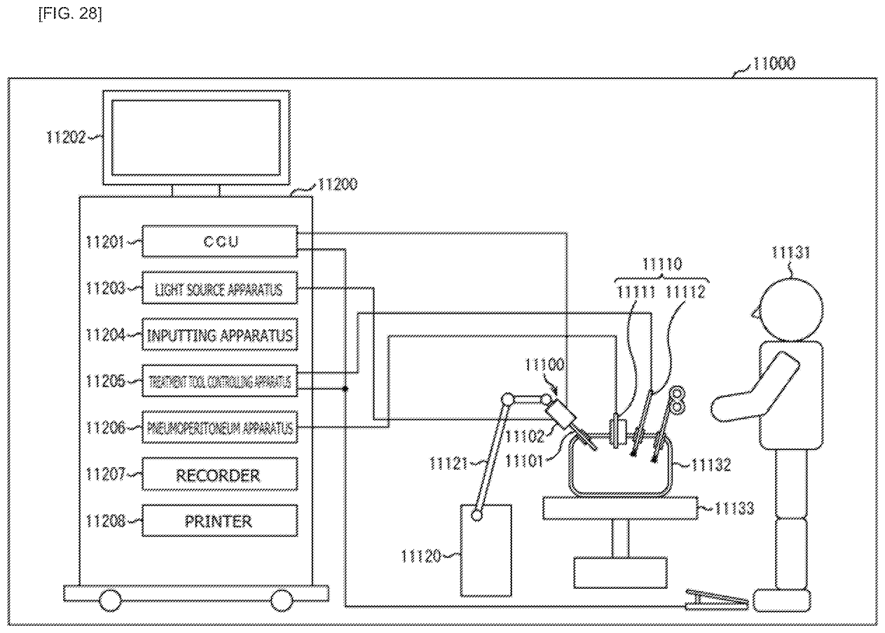

FIG. 27 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 27, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

An example of the in-vivo information acquisition system to which the technology according to the present disclosure may be applied has been described above. The technology according to the present disclosure may be applied, for example, to the image pickup unit 10112 among the components described above. This makes it possible to increase the detection accuracy.

### Application Example 4

### [Example of Practical Application to Endoscopic Surgery System]

The technology (present technology) according to the present disclosure is applicable to various products. For example, the technology according to the present disclosure may be applied to an endoscopic surgery system.

FIG. 28 is a view depicting an example of a schematic configuration of an endoscopic surgery system to which the technology according to an embodiment of the present disclosure (present technology) can be applied.

In FIG. 28, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endo scope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

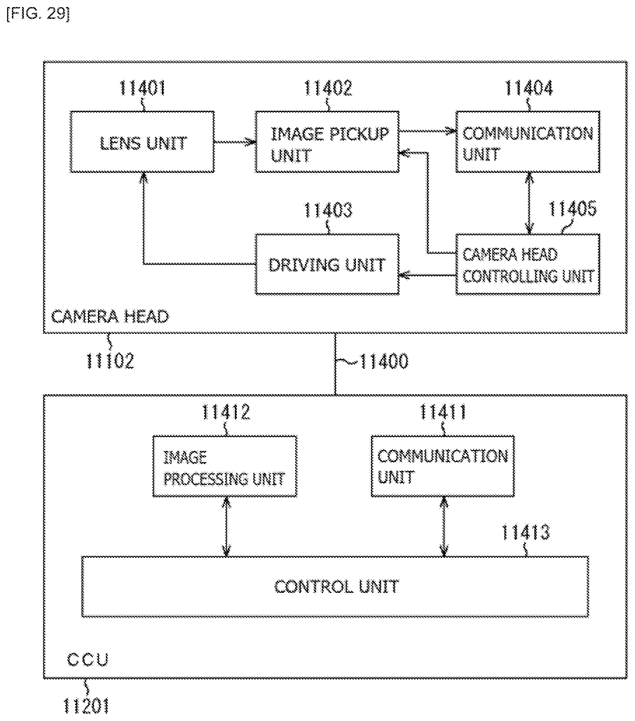

FIG. 29 is a block diagram depicting an example of a functional configuration of the camera head 11102 and the CCU 11201 depicted in FIG. 28.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure may be applied has been described above. The technology according to the present disclosure may be applied to the image pickup unit 11402 among the components described above. Applying the technology according to an embodiment of the present disclosure to the image pickup unit 11402 increases the detection accuracy.

It is to be noted that the endoscopic surgery system has been described here as an example, but the technology according to the present disclosure may be additionally applied to, for example, a microscopic surgery system or the like.

### Application Example 5

### [Example of Practical Application to Mobile Body]

The technology according to the present disclosure is applicable to various products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

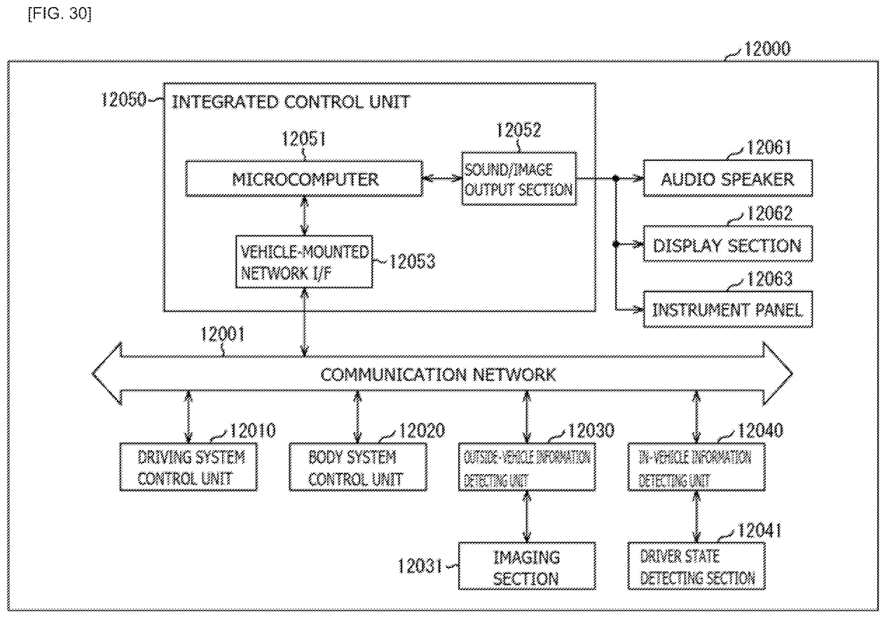

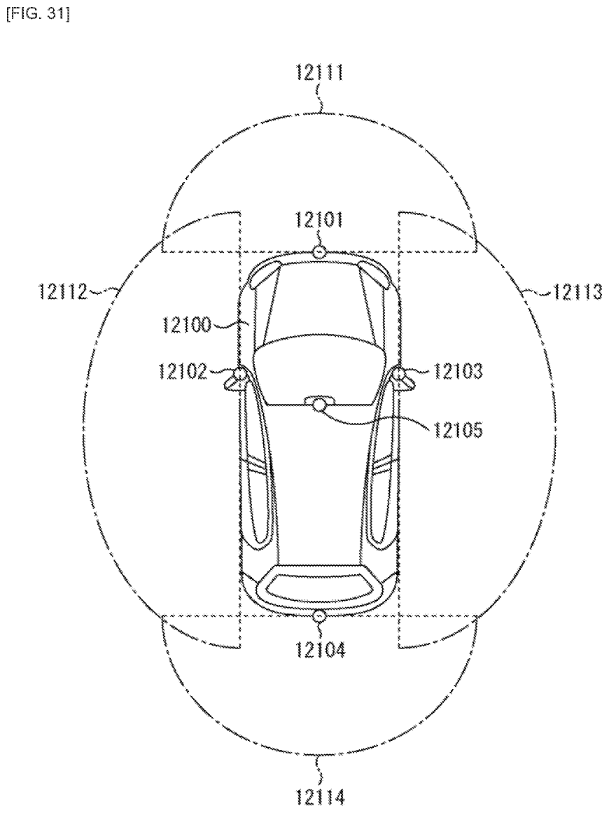

FIG. 30 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 30, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 30, an audio speaker 12061, a display section 12062, and an instrument panel 12063 are illustrated as the output device. The display section 12062 may, for example, include at least one of an on-board display and a head-up display.

FIG. 31 is a diagram depicting an example of the installation position of the imaging section 12031.

In FIG. 31, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 31 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Although the description has been given by referring to the first to third embodiments and the modification examples 1 to 5, the present disclosure is not limited to the above-described embodiments and the like, and may be modified in a variety of ways. For example, in the above-described embodiments, the photoelectric conversion element has a configuration in which the organic photoelectric converter 11G detecting green light and the inorganic photoelectric converters 11B and 11R respectively detecting blue light and red light are stacked; however, the contents of the present disclosure is not limited to such a configuration. That is, the organic photoelectric converter may detect red light or blue light, and the inorganic photoelectric converter may detect green light.

In the above-described embodiments and the like, the configurations of the solid-state imaging elements 1 and 10A of the back-side illumination type are exemplified; however, the present disclosure is also applicable to a front-side illumination type.

Further, an inner lens (not illustrated) may be disposed between the light reception section 20 and the color filter 43 (or 54) of the light condensing section 40 (or 50).

In addition, it is not necessary to include all of the components described in the above embodiments and the like, and other components may be included.

It is to be noted that the present disclosure may have the following configurations.

(1)

A solid-state imaging element including:

a semiconductor substrate having a photoelectric converter for each of pixels;

a pixel separation groove provided between the pixels, the pixel separation groove extending from one surface of the semiconductor substrate toward another surface of the semiconductor substrate that opposes the one surface; and

a pixel coupling section provided between the pixels on the other surface of the semiconductor substrate.

(2)

The solid-state imaging element according to (1), in which the one surface is a light incident surface of the semiconductor substrate, and the pixels on side on which the light incident surface is provided are separated from each other by the pixel separation groove.

(3)

The solid-state imaging element according to (1) or (2), in which the one surface is a transistor surface that opposes a light incident surface of the semiconductor substrate, and the pixels on side on which the transistor surface is provided are separated from each other by the pixel separation groove.

(4)

The solid-state imaging element according to (2) or (3), in which

the semiconductor substrate includes a p-type semiconductor region on side on which the transistor surface is provided, and

the pixel coupling section includes the p-type semiconductor region.

(5)

The solid-state imaging element according to (4), in which a side surface of the pixel separation groove includes, as compared to the p-type semiconductor region, a p-type semiconductor region having a high impurity concentration.

(6)

The solid-state imaging element according to any one of (1) to (5), in which the pixel coupling section has a thickness of 1 μm or less.

(7)

The solid-state imaging element according to any one of (1) to (6), in which the pixel coupling section has a width of 1 μm or less.

(8)

The solid-state imaging element according to any one of (1) to (7), in which the pixel separation groove is filled with silicon oxide (SiO₂).

(9)

The solid-state imaging element according to any one of (1) to (8), in which the semiconductor substrate has a low-reflective film formed on side on which a light incident surface is provided, the low-reflective film including any one of hafnium oxide (HfO₂), zinc oxide (ZnO₂), aluminum oxide (Al₂O₃), titanium oxide (TiO₂), and tantalum oxide (Ta₂O₅).

(10)

A method of manufacturing a solid-state imaging element, the method including:

forming a pixel separation groove between pixels of a semiconductor substrate, the pixel separation groove extending from one surface of the semiconductor substrate toward another surface of the semiconductor substrate that opposes the one surface;

providing a pixel coupling section between the pixels on the other surface of the semiconductor substrate; and

forming a photoelectric converter for each of the pixels.

(11)

The method of manufacturing the solid-state imaging element according to (10), in which the method includes

forming a hard mask or a resist film on the other surface of the semiconductor substrate and forming the pixel separation groove by leaving a portion of the other surface, and

ion-implanting boron (B) with a tilt from side on which the other surface is provided using the hard mask or the resist film as a mask, and thereafter forming the pixel coupling section by selective etching.

(12)

An electronic apparatus including a solid-state imaging element,

the solid-state imaging element including
a semiconductor substrate having a photoelectric converter for each of pixels;
a pixel separation groove provided between the pixels, the pixel separation groove extending from one surface of the semiconductor substrate toward another surface of the semiconductor substrate that opposes the one surface; and
a pixel coupling section provided between the pixels on the other surface of the semiconductor substrate.

This application claims the benefit of Japanese Priority Patent Application JP2018-114546 filed with the Japan Patent Office on Jun. 15, 2018, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A solid-state imaging element comprising:
a semiconductor substrate having a photoelectric converter for each of pixels;
a pixel separation groove provided between the pixels, the pixel separation groove extending from one surface of the semiconductor substrate toward another surface of the semiconductor substrate that opposes the one surface; and
a pixel coupling section provided between the pixels on the other surface of the semiconductor substrate.

2. The solid-state imaging element according to claim 1, wherein the one surface is a light incident surface of the semiconductor substrate, and the pixels on side on which the light incident surface is provided are separated from each other by the pixel separation groove.

3. The solid-state imaging element according to claim 1, wherein the one surface is a transistor surface that opposes a light incident surface of the semiconductor substrate, and the pixels on side on which the transistor surface is provided are separated from each other by the pixel separation groove.

4. The solid-state imaging element according to claim 2, wherein
the semiconductor substrate includes a p-type semiconductor region on side on which the transistor surface is provided, and
the pixel coupling section includes the p-type semiconductor region.

5. The solid-state imaging element according to claim 4, wherein a side surface of the pixel separation groove includes, as compared to the p-type semiconductor region, a p-type semiconductor region having a high impurity concentration.

6. The solid-state imaging element according to claim 1, wherein the pixel coupling section has a thickness of 1 μm or less.

7. The solid-state imaging element according to claim 1, wherein the pixel coupling section has a width of 1 μm or less.

8. The solid-state imaging element according to claim 1, wherein the pixel separation groove is filled with silicon oxide (SiO₂).

9. The solid-state imaging element according to claim 1, wherein the semiconductor substrate has a low-reflective film formed on side on which a light incident surface is provided, the low-reflective film including any one of hafnium oxide (HfO₂), zinc oxide (ZnO₂), aluminum oxide (Al₂O₃), titanium oxide (TiO₂), and tantalum oxide (Ta₂O₅).

10. A method of manufacturing a solid-state imaging element, the method comprising:
forming a pixel separation groove between pixels of a semiconductor substrate, the pixel separation groove extending from one surface of the semiconductor substrate toward another surface of the semiconductor substrate that opposes the one surface;
providing a pixel coupling section between the pixels on the other surface of the semiconductor substrate; and
forming a photoelectric converter for each of the pixels.

11. The method of manufacturing the solid-state imaging element according to claim 10, wherein the method comprises
forming a hard mask or a resist film on the other surface of the semiconductor substrate and forming the pixel separation groove by leaving a portion of the other surface, and
ion-implanting boron (B) with a tilt from side on which the other surface is provided using the hard mask or the resist film as a mask, and thereafter forming the pixel coupling section by selective etching.

12. An electronic apparatus comprising a solid-state imaging element,
the solid-state imaging element including
a semiconductor substrate having a photoelectric converter for each of pixels;
a pixel separation groove provided between the pixels, the pixel separation groove extending from one surface of the semiconductor substrate toward another surface of the semiconductor substrate that opposes the one surface; and
a pixel coupling section provided between the pixels on the other surface of the semiconductor substrate.
